(19) United States
(12) Patent Application Publication
(10) Pub. No.: US 2025/0212398 A1
(43) Pub. Date: Jun. 26, 2025

(54) SEMICONDUCTOR DEVICES

(71) Applicant: Samsung Electronics Co., Ltd., Suwon-si (KR)

(72) Inventors: Seokjun Hong, Suwon-si (KR); Sohyeon Park, Suwon-si (KR); Hyeongho So, Suwon-si (KR); Yanghee Lee, Suwon-si (KR); JongHan Jeong, Suwon-si (KR); Jeonghwa Heo, Suwon-si (KR)

(21) Appl. No.: 18/813,722

(22) Filed: Aug. 23, 2024

(30) Foreign Application Priority Data
Dec. 20, 2023 (KR) 10-2023-0187396

(51) Int. Cl. H10B 12/00

(52) U.S. Cl. CPC H10B 12/50; H10B 12/315

(57) ABSTRACT

A semiconductor device may include a substrate, and an interconnection layer on the substrate. The interconnection layer may include an insulating layer, a conductive line, and a conductive contact, and the insulating layer may include an upper insulating layer on a lower insulating layer. The conductive contact may extend into a lower portion of the upper insulating layer and extend into the lower insulating layer, and the conductive line may be on the lower insulating layer and intersects the upper insulating layer. The upper insulating layer may include a low-k dielectric material.

### CROSS-REFERENCE TO RELATED APPLICATIONS

This U.S. non-provisional patent application claims priority under 35 U.S.C. § 119 to Korean Patent Application No. 10-2023-0187396, filed on Dec. 20, 2023, in the Korean Intellectual Property Office, the entire contents of which are hereby incorporated by reference.

### BACKGROUND

The present disclosure relates to a semiconductor device and a method of fabricating the same, and in particular, to a semiconductor device including a metal line and a method of fabricating the same.

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

Due to the recent increasing demand for electronic devices with a fast speed and/or low power consumption, the semiconductor device may need a faster operating speed and/or a lower operating voltage. To satisfy the demand, it is necessary to increase an integration density of the semiconductor device. However, an increase in the integration density of the semiconductor device may lead to deterioration in reliability of the semiconductor device. In addition, as the electronics industry is highly developed, there is an increasing demand for a highly-reliable semiconductor device. Thus, many studies are being conducted to realize a highly-integrated and highly-reliable semiconductor device.

### SUMMARY

Embodiments of the inventive concept provides a semiconductor device with improved electrical characteristics and a method of fabricating the same.

According to some embodiments of the inventive concept, a semiconductor device may include a substrate, and an interconnection layer on the substrate. The interconnection layer may include an insulating layer, a conductive line, and a conductive contact, and the insulating layer may include an upper insulating layer on a lower insulating layer. The conductive contact may extend into a lower portion of the upper insulating layer and extend into the lower insulating layer, and the conductive line may be on the lower insulating layer and intersect the upper insulating layer. The upper insulating layer may include a low-k dielectric material.

According to some embodiments of the inventive concept, a semiconductor device may include a substrate, a cell structure on the substrate, and an interconnection layer on the cell structure. The interconnection layer may include an insulating layer, a conductive line, and a conductive contact, and the insulating layer may include an upper insulating layer on a lower insulating layer. The conductive contact may include a first portion and a second portion on the first portion. The first portion may extend into the lower insulating layer, and the second portion may extend into a lower portion of the upper insulating layer. The first portion may have a first width in a first direction parallel to a top surface of the substrate, and the second portion may have a second width in the first direction. The first width may decrease, as a distance to the top surface of the substrate, in a second direction perpendicular to the top surface of the substrate, decreases. The second width may be substantially constant in the second direction.

According to some embodiments of the inventive concept, a semiconductor device may include a semiconductor substrate including a cell region and a peripheral region adjacent the cell region and including cell active patterns on the cell region, word lines on the semiconductor substrate that intersect the cell active patterns, bit lines on the semiconductor substrate that intersect the word lines, a storage node contact on an end portion of each of the cell active patterns, a landing pad on the storage node contact, a capacitor on the landing pad, and an interconnection layer on the capacitor. The interconnection layer may include an insulating layer, a plurality of conductive contacts, and a plurality of conductive lines, which are spaced apart from each other in a first direction parallel to a top surface of the semiconductor substrate. The insulating layer may include an upper insulating layer on a lower insulating layer. Each of the conductive contacts extends into a lower portion of the upper insulating layer and extends into the lower insulating layer. A first conductive line of the plurality of conductive lines extends into an upper portion of a first conductive contact of the plurality of conductive contacts. The upper insulating layer may include a first dielectric material, and the lower insulating layer may include a second dielectric material. A first dielectric constant of the first dielectric material may be less than a second dielectric constant of the second dielectric material.

### BRIEF DESCRIPTION OF THE DRAWINGS

FIG. 1 is a plan view illustrating a cell structure of a semiconductor device according to some embodiments of the inventive concept.

FIG. 2 is a sectional view illustrating a semiconductor device according to some embodiments of the inventive concept.

FIG. 3 is an enlarged sectional view illustrating a portion ‘CU1’ of FIG. 2.

FIG. 4 is an enlarged sectional view illustrating a semiconductor device according to a comparative example and corresponding to the portion ‘CU1’ of FIG. 2.

FIGS. 5, 6A, 7A, 8A, and 9A are sectional views illustrating a process of fabricating a semiconductor device, according to some embodiments of the inventive concept.

FIGS. 6B, 7B, 8B, and 9B are enlarged sectional views illustrating a portion ‘CU2’ of FIG. 6A, a portion ‘CU3’ of FIG. 7A, a portion ‘CU4’ of FIG. 8A, and a portion ‘CU5’ of FIG. 9A.

### DETAILED DESCRIPTION

Example embodiments of the inventive concepts will now be described more fully with reference to the accompanying drawings, in which example embodiments are shown.

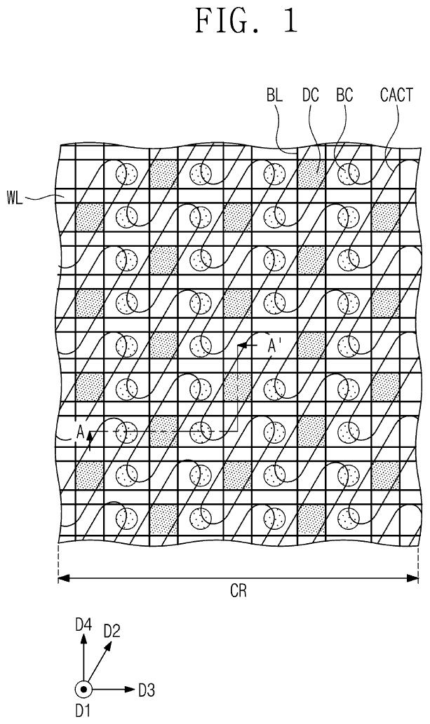

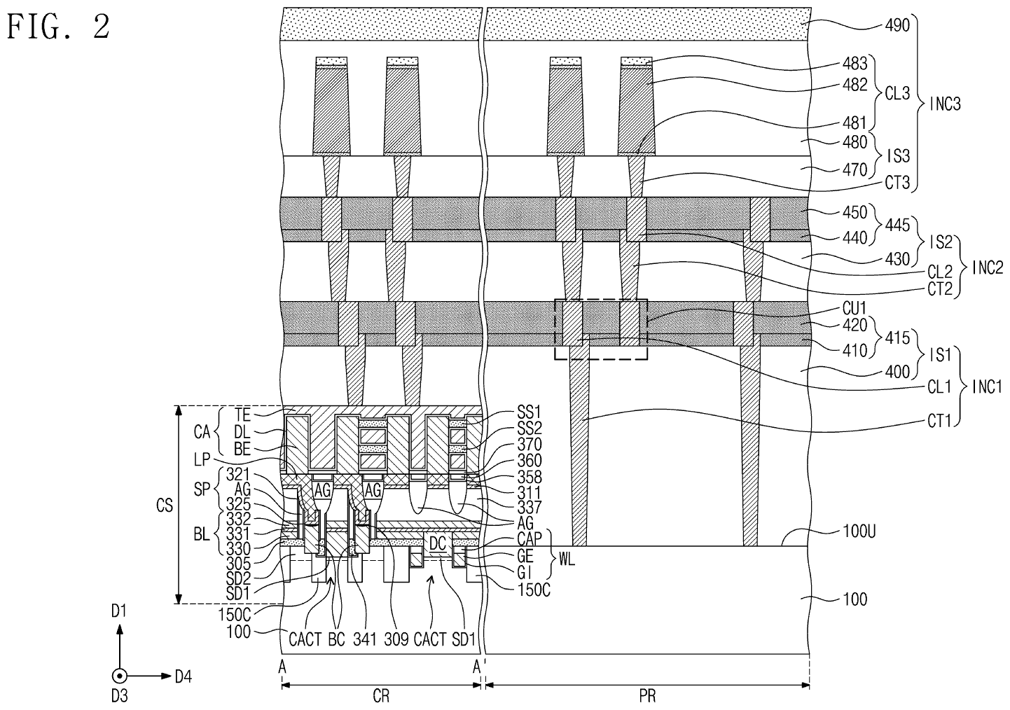

FIG. 1 is a plan view illustrating a cell structure of a semiconductor device according to some embodiments of the inventive concept. FIG. 2 is a sectional view illustrating a semiconductor device according to some embodiments of the inventive concept, concretely illustrating a cell region portion and a peripheral region taken along a line A-A′ of FIG. 1.

Referring to FIGS. 1 and 2, a substrate 100 including a cell region CR and a peripheral region PR may be provided. The substrate 100 may be a semiconductor substrate (e.g., a silicon substrate, a germanium substrate, or a silicon-germanium substrate). A cell structure CS may be disposed on the cell region CR of the substrate 100, and peripheral circuits may be disposed on the peripheral region PR of the substrate 100.

The cell structure CS may include cell device isolation patterns 150C, which are disposed in the cell region CR of the substrate 100. The cell device isolation patterns 150C may define cell active patterns CACT. The cell active patterns CACT may be portions of the substrate 100 that protrude in a first direction D1.

In the present specification, the first direction D1 may be defined as a direction that is perpendicular to a top surface 100U of the substrate 100. A second direction D2 may be defined as a direction parallel to the top surface of the substrate 100. A third direction D3 may be defined as a direction parallel to the top surface of the substrate 100. A fourth direction D4 may be defined as a direction that is parallel to the top surface 100U of the substrate 100 and is perpendicular to the third direction D3. The second direction D2 may be defined as a direction that is parallel to the top surface 100U of the substrate 100 and is not parallel to the third and fourth directions D3 and D4.

Each of the cell active patterns CACT may be a bar-shaped pattern elongated in the second direction D2. The cell device isolation patterns 150C may be interposed between the cell active patterns CACT and may be formed of or include at least one of oxide, nitride, and/or oxynitride.

The cell structure CS may include word lines WL disposed on the cell region CR of the substrate 100. The word lines WL may be provided to cross the cell active patterns CACT and the cell device isolation patterns 150C. The word lines WL may be extended in the third direction D3 and may be spaced apart from each other in the fourth direction D4. Each of the word lines WL may include a cell gate electrode GE, which is buried in the substrate 100, a cell gate dielectric pattern GI, which is interposed between the cell gate electrode GE and the cell active patterns CACT and between the cell gate electrode GE and the cell device isolation patterns 150C, and a cell gate capping pattern CAP, which is provided on a top surface of the cell gate electrode GE. The cell gate electrode GE may include a conductive material. In some embodiments, the conductive material may be one of doped semiconductor materials (e.g., doped silicon or doped germanium), conductive metal nitrides (e.g., titanium nitride or tantalum nitride), metallic materials (e.g., tungsten, titanium, or tantalum), and/or metal-semiconductor compounds (e.g., tungsten silicide, cobalt silicide, or titanium silicide). The cell gate dielectric pattern GI may include, for example, a silicon oxide layer, a silicon nitride layer, and/or a silicon oxynitride layer. The cell gate capping pattern CAP may include, for example, a silicon oxide layer, a silicon nitride layer, and/or a silicon oxynitride layer.

The cell structure CS may include a first impurity region SD1 and a second impurity regions SD2, which are disposed in each of the cell active patterns CACT. The second impurity regions SD2 may be spaced apart from each other, with the first impurity region SD1 interposed therebetween. The first impurity region SD1 may be provided between a pair of word lines WL, which are provided to cross the cell active patterns CACT. The second impurity regions SD2 may be spaced apart from each other, with the pair of word lines WL interposed therebetween. The first impurity region SD1 may be doped to have the same conductivity type as the second impurity regions SD2.

The cell structure CS may include an insulating layer 305 on the cell region CR of the substrate 100, the bit lines BL on the insulating layer 305, and the bit line capping patterns 337 on the bit lines BL. The insulating layer 305 may cover, overlap, or be on the word lines WL and the cell active patterns CACT. The bit lines BL may be disposed on the substrate 100 to cross or intersect the word lines WL. The bit lines BL may be disposed to cross the word lines WL. The bit lines BL may be extended in the fourth direction D4 and may be spaced apart from each other in the third direction D3. Each of the bit lines BL may include a polysilicon pattern 330, an ohmic pattern 331, and a metal-containing pattern 332, which are sequentially stacked in the first direction D1. The bit line capping patterns 337 may be disposed on the bit lines BL, respectively. The bit line capping patterns 337 may be formed of or include at least one of insulating materials (e.g., silicon nitride).

The cell structure CS may include bit line contacts DC, which are disposed below each of the bit lines BL. The bit line contacts DC may be disposed below each of the bit lines BL and may be spaced apart from each other in the fourth direction D4. Each of the bit line contacts DC may be electrically connected to the first impurity region SD1. The bit line contacts DC may be formed of or include at least one of doped semiconductor materials (e.g., doped silicon and/or doped germanium), conductive metal nitrides (e.g., titanium nitride and/or tantalum nitride), metallic materials (e.g., tungsten, titanium, and/or tantalum), or metal-semiconductor compounds (e.g., tungsten silicide, cobalt silicide, and/or titanium silicide). The cell structure CS may include a lower insulating gapfill layer 341, which is disposed on a side surface of each of the bit line contacts DC.

The cell structure CS may include storage node contacts BC, which are disposed between an adjacent pair of the bit lines BL, and a bit line spacer SP, which is interposed between each of the bit lines BL and the storage node contacts BC. The storage node contacts BC may be provided on opposite end portions of each of the cell active patterns CACT and may be spaced apart from each other in the fourth direction D4. The storage node contacts BC may be formed of or include doped or undoped polysilicon. The bit line spacer SP may include a first sub-spacer 321 and a second sub-spacer 325, which are spaced apart from each other by an air gap AG. The first sub-spacer 321 may cover, overlap, or be on a side surface of each of the bit lines BL and a side surface of each of the bit line capping patterns 337. The second sub-spacer 325 may be adjacent to the storage node contacts BC. The first sub-spacer 321 and the second sub-spacer 325 may be formed of or include the same material (e.g., silicon nitride).

The cell structure CS may include a storage node ohmic layer 309 disposed on each of the storage node contacts BC, a diffusion prevention pattern 311 provided on the storage node ohmic layer 309, and a landing pad LP provided on the diffusion prevention pattern 311. The storage node ohmic layer 309 may be formed of or include metal silicide. The diffusion prevention pattern 311 may conformally cover, overlap, or be on the storage node ohmic layer 309, the first and second sub-spacers 321 and 325, and the bit line capping patterns 337. The diffusion prevention pattern 311 may be formed of or include at least one of metal nitrides (e.g., titanium nitride or tantalum nitride). The landing pad LP may be formed of or include a metal-containing material (e.g., tungsten). An upper portion of the landing pad LP may have a width that is larger than that of the storage node contact BC. The upper portion of the landing pad LP may be shifted from the storage node contact BC in a direction parallel to the top surface 100U of the substrate 100.

The cell structure CS may include a first capping pattern 358 and a second capping pattern 360, which are interposed between adjacent ones of the landing pads LP. Each of the first and second capping patterns 358 and 360 may be formed of or include at least one of silicon nitride, silicon oxide, silicon oxynitride, or porous materials. The air gap AG between the first and second sub-spacers 321 and 325 may be extended into regions between the landing pads LP. The first capping pattern 358, the bit line capping pattern 337, and the landing pad LP may be partially exposed by the air gap AG.

The cell structure CS may include a capacitor CA, which is provided on the cell region CR of the substrate 100. The capacitor CA may include bottom electrodes BE disposed on the landing pads LP, respectively, a top electrode TE covering, overlapping, or on the bottom electrodes BE, and a dielectric layer DL interposed between each of the bottom electrodes BE and the top electrode TE. The bottom electrodes BE may be formed of or include at least one of doped poly-silicon, metal nitride materials (e.g., titanium nitride), or metallic materials (e.g., tungsten, aluminum, and/or copper). Each of the bottom electrodes BE may be shaped like a circular pillar, a hollow cylinder, or a cup.

The cell structure CS may include an upper supporting pattern SS1 and a lower supporting pattern SS2, which are provided to support the bottom electrodes BE. The upper supporting pattern SS1 may be provided to support upper side surfaces of the bottom electrodes BE, and the lower supporting pattern SS2 may be provided to support lower side surfaces of the bottom electrodes BE. The upper and lower supporting patterns SS1 and SS2 may be formed of or include at least one of insulating materials (e.g., silicon nitride, silicon oxide, and/or silicon oxynitride). The cell structure CS may include an etch stop layer 370, which is provided between the bottom electrodes BE to cover, overlap, or be on the first and second capping patterns 358 and 360. The etch stop layer 370 may be formed of or include at least one of insulating materials (e.g., silicon nitride, silicon oxide, and/or silicon oxynitride).

The dielectric layer DL may be provided to cover, overlap, or be on surfaces of the bottom electrodes BE and surfaces of the upper and lower supporting patterns SS1 and SS2. The top electrode TE may be disposed on the dielectric layer DL to fill a space between the bottom electrodes BE. The top electrode TE may be formed of or include at least one of doped poly-silicon, doped silicon germanium, metal nitride materials (e.g., titanium nitride), or metallic materials (e.g., tungsten, aluminum, and/or copper).

A first interconnection layer INC1, a second interconnection layer INC2, and a third interconnection layer INC3 may be sequentially stacked on the substrate 100 and the cell structure CS in the first direction D1. The first interconnection layer INC1 may be the lowermost one of the interconnection layers INC1, INC2, and INC3, and the third interconnection layer INC3 may be the uppermost one of the interconnection layers INC1, INC2, and INC3. FIG. 2 illustrates an example, in which three interconnection layers INC1, INC2, and INC3 are provided, but the inventive concept is not limited to this example. Additional interconnection layers may be provided between the lowermost interconnection layer (i.e., INC1) and the uppermost interconnection layer (i.e., INC3).

The first interconnection layer INC1 may include a first interconnection insulating layer IS1, first conductive contacts CT1, and first conductive lines CL1.

The first interconnection insulating layer IS1 may include a first lower insulating layer 400 and a first upper insulating layer 415, which are sequentially stacked on the cell and peripheral regions CR and PR in the first direction D1.

In detail, the first lower insulating layer 400 may be disposed on the cell and peripheral regions CR and PR of the substrate 100. The first lower insulating layer 400 may cover, overlap, or be on the cell structure CS of the cell region CR and may cover, overlap, or be on the peripheral region PR (e.g., the peripheral circuit) of the substrate. The first lower insulating layer 400 may include a first dielectric material. The first dielectric material may be formed of or include silicon oxide (e.g., tetraethyl orthosilicate (TEOS; Si (OC₂H₅)₄)).

The first upper insulating layer 415 may be disposed on the first lower insulating layer 400. The first upper insulating layer 415 may include a second dielectric material. The second dielectric material may include a low-k dielectric material which has a higher etch rate and a lower dielectric constant than the first dielectric material in the first lower insulating layer 400. The second dielectric material in the first upper insulating layer 415 may have a dielectric constant of 3.5 or lower. In some embodiments, the second dielectric material may be formed of or include at least one of SiCOH, SiOF, or polyimide.

Here, the first upper insulating layer 415 may include a first low-k dielectric layer 410 and a second low-k dielectric layer 420, which are sequentially stacked on the first lower insulating layer 400. The first low-k dielectric layer 410 may correspond to a lower portion of the first upper insulating layer 415. The second low-k dielectric layer 420 may correspond to an upper portion of the first upper insulating layer 415. A bottom surface of the first low-k dielectric layer 410 may be in contact with a top surface of the first lower insulating layer 400. Unlike the illustrated example, there may be no observable boundary between the first low-k dielectric layer 410 and the second low-k dielectric layer 420.

The first conductive contacts CT1 may be disposed on the cell and peripheral regions CR and PR of the substrate 100. In some embodiments, a plurality of first conductive contacts CT1 may be arranged in the fourth direction D4. In detail, at least one of the first conductive contacts CT1 may be provided to penetrate or extend into the first lower insulating layer 400 and a lower portion of the first upper insulating layer 415 and may be connected to the top electrode TE of the capacitor CA, and others of the first conductive contacts CT1 may be provided to penetrate or extend into the first lower insulating layer 400 and the lower portion of the first upper insulating layer 415 and may be electrically connected to the substrate 100 (e.g., the peripheral circuit) on the peripheral region PR. Here, a portion of a top surface of the first conductive contact CT1 may be in contact with a bottom surface of the second low-k dielectric layer 420. A level of the top surface of the first lower insulating layer 400 may be lower than a level of the top surface of the first conductive contact CT1 with respect to the substrate. The first conductive contacts CT1 may be formed of or include at least one of metallic materials (e.g., copper, tungsten, and/or aluminum) or conductive metal nitride materials.

The first conductive lines CL1 may be disposed on the first lower insulating layer 400. In some embodiments, a plurality of first conductive lines CL1 may be arranged in the fourth direction D4 to cross or intersect the first upper insulating layer 415. That is, the first upper insulating layer 415 may cover, overlap, or be on a side surface of each of the first conductive lines CL1. In detail, at least one of the first conductive lines CL1 may be provided to penetrate or extend into the first upper insulating layer 415 and an upper portion of the first conductive contact CT1 and may be disposed on the first lower insulating layer 400. Others of the first conductive lines CL1 may be provided to penetrate or extend into the first upper insulating layer 415 and to be in contact with the top surface of the first lower insulating layer 400. The first conductive lines CL1 may be formed of or include at least one of metallic materials (e.g., copper, tungsten, and/or aluminum) or conductive metal nitride materials.

The second interconnection layer INC2 may be disposed on the first interconnection layer INC1. The second interconnection layer INC2 may include a second interconnection insulating layer IS2, second conductive contacts CT2, and second conductive lines CL2.

The second interconnection insulating layer IS2 may include a second lower insulating layer 430 and a second upper insulating layer 445, which are sequentially stacked on the cell and peripheral regions CR and PR in the first direction D1.

In detail, the second lower insulating layer 430 may be disposed on the first upper insulating layer 415. The second lower insulating layer 430 may be formed of or include the same dielectric material (e.g., the first dielectric material) as the first lower insulating layer 400. In some embodiments, the first dielectric material may be formed of or include silicon oxide (e.g., Tetraethyl orthosilicate (TEOS; Si (OC₂H₅)₄)).

The second upper insulating layer 445 may be disposed on the second lower insulating layer 430. The second upper insulating layer 445 may include the same second dielectric material as the first upper insulating layer 415. The second dielectric material may include a low-k dielectric material which has a higher etch rate and a lower dielectric constant than the first dielectric material in the second lower insulating layer 430. The second dielectric material in the second upper insulating layer 445 may have a dielectric constant of 3.5 or lower. In some embodiments, the second dielectric material may be formed of or include at least one of SiCOH, SiOF, or polyimide.

Here, the second upper insulating layer 445 may include a third low-k dielectric layer 440 and a fourth low-k dielectric layer 450, which are sequentially stacked on the second lower insulating layer 430. The third low-k dielectric layer 440 may correspond to a lower portion of the second upper insulating layer 445. The fourth low-k dielectric layer 450 may correspond to an upper portion of the second upper insulating layer 445. A bottom surface of the third low-k dielectric layer 440 may be in contact with a top surface of the second lower insulating layer 430.

The second conductive contacts CT2 may be disposed on the first interconnection layer INC1. In some embodiments, a plurality of second conductive contacts CT2 may be arranged in the fourth direction D4. The second conductive contacts CT2 may be provided to penetrate or extend into the second lower insulating layer 430 and a lower portion of the second upper insulating layer 445 and may be connected to a corresponding one of the first conductive lines CL1. The second conductive contacts CT2 may be formed of or include at least one of metallic materials (e.g., copper, tungsten, and/or aluminum) or conductive metal nitride materials.

The second conductive lines CL2 may be disposed on the second lower insulating layer 430. In some embodiments, a plurality of second conductive lines CL2 may be arranged in the fourth direction D4. In detail, the second conductive lines CL2 may be provided to penetrate or extend into the second upper insulating layer 445 and an upper portion of the second conductive contact CT2 and may be disposed on the second lower insulating layer 430. The second conductive lines CL2 may be formed of or include at least one of metallic materials (e.g., copper, tungsten, and/or aluminum) or conductive metal nitride materials.

The third interconnection layer INC3 may be disposed on the second interconnection layer INC2. The third interconnection layer INC3 may include a third interconnection insulating layer IS3, third conductive contacts CT3, and third conductive lines CL3.

The third interconnection insulating layer IS3 may include a third lower insulating layer 470, a passivation layer 480, and a protection layer 490, which are provided on the cell and peripheral regions CR and PR and are sequentially stacked in the first direction D1.

In detail, the third lower insulating layer 470 may be disposed on the second upper insulating layer 445. The third lower insulating layer 470 may be formed of or include silicon oxide. In some embodiments, the third lower insulating layer 470 may be formed of or include Tetraethyl orthosilicate (TEOS; Si (OC₂H₅)₄).

The passivation layer 480 may be disposed on the third lower insulating layer 470. The passivation layer 480 may be formed of or include a hydrogen-containing insulating material. The protection layer 490 may be disposed on the passivation layer 480. The protection layer 490 may be formed of or include, for example, silicon nitride.

The third conductive contacts CT3 may be disposed on the second interconnection layer INC2. In some embodiments, a plurality of third conductive contacts CT3 may be arranged in the fourth direction D4. The third conductive contacts CT3 may be provided to penetrate or extend into the third lower insulating layer 470 and may be connected to a corresponding one of the second conductive lines CL2. The third conductive contacts CT3 may be formed of or include at least one of metallic materials (e.g., copper, tungsten, and/or aluminum) or conductive metal nitride materials.

The third conductive lines CL3 may be disposed on the third lower insulating layer 470. The third conductive lines CL3 may be arranged in the fourth direction D4 and may be disposed on corresponding ones of the third conductive contacts CT3. Here, the passivation layer 480 may cover, overlap, or be on the third conductive lines CL3.

Each of the third conductive lines CL3 may include a metal compound pattern 481, a metal pattern 482, and a capping pattern 483, which are sequentially stacked in the first direction D1. The metal compound pattern 481 and the metal pattern 482 may be formed of or include the same metallic material. The metal compound pattern 481 may be in contact with a bottom surface of the metal pattern 482. The capping pattern 483 may be in contact with a top surface of the metal pattern 482. The metal compound pattern 481 may be interposed between the capping pattern 483 and the metal pattern 482. In some embodiments, the metal compound pattern 481 and the metal pattern 482 may be formed of or include at least one of metallic materials (e.g., copper, tungsten, and/or aluminum) or conductive metal nitride materials, and the capping pattern 483 may be formed of or include at least one of Ta, TaN, Ti, or TiN.

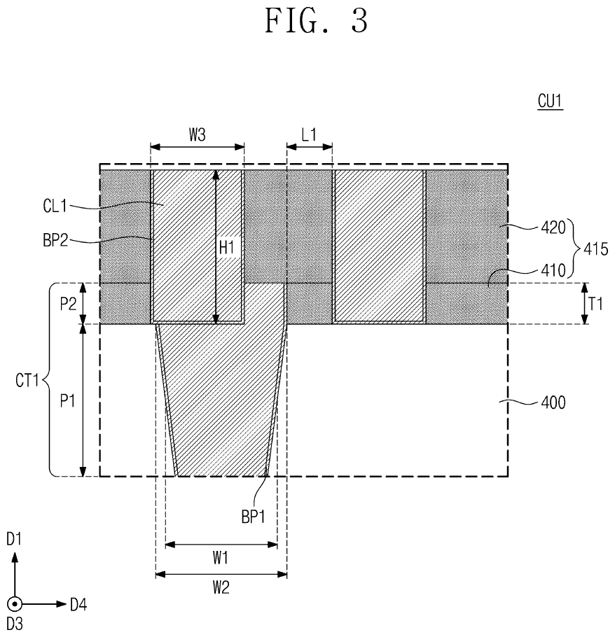

FIG. 3 is an enlarged sectional view illustrating a portion ‘CU1’ of FIG. 2.

Referring to FIG. 3, the first conductive contact CT1 may include a first portion P1 and a second portion P2 on the first portion P1. The first portion PI may be a lower portion of the first conductive contact CT1, which is provided to penetrate or extend into the first lower insulating layer 400. The second portion P2 may be an upper portion of the first conductive contact CT1, which is provided to penetrate or extend into the lower portion of the first upper insulating layer 415. That is, the second portion P2 may be a portion of the first conductive contact CT1 penetrating the first low-k dielectric layer 410. The second portion P2 may be disposed on the first lower insulating layer 400.

The first portion P1 may have a first width W1 in the fourth direction D4. Here, referring to FIG. 2, the first portion P1 may have a tapered shape. For example, the first width W1 may decrease as a distance to the top surface 100U of the substrate 100 in the first direction D1 decreases. The second portion P2 may have a second width W2 in the fourth direction D4. The second width W2 may be constant regardless of a position in the first direction D1. In other words, a width of the first conductive contact CT1 in the fourth direction D4 may be substantially constant from a level of a bottom surface of the first conductive line CL1 to a level of the top surface of the first conductive contact CT1.

A first barrier metal BP1 may be disposed on side and bottom surfaces of the first conductive contact CT1. The first barrier metal BP1 may be provided between the first conductive contact CT1 and the first lower insulating layer 400 and between the first conductive contact CT1 and the first upper insulating layer 415. The first barrier metal BP1 may be formed of or include at least one of titanium (Ti), titanium nitride (TiN), or tungsten (W). The first barrier metal BP1 may prevent a metallic material, which is included in the first conductive contact CT1, from being diffused into the first lower insulating layer 400 and the first upper insulating layer 415.

The first conductive lines CL1 may be provided to penetrate or extend into the first upper insulating layer 415. At least one of the first conductive lines CL1 may be provided to penetrate or extend into a portion of the second portion P2 of the first conductive contact CT1 and may be electrically connected to the first conductive contact CT1.

The first conductive line CL1 may have a third width W3 in the fourth direction D4. The third width W3 may be substantially constant from the bottom surface of the first conductive line CL1 to the top surface of the first conductive line CL1. The first conductive line CL1 may have a first height H1 in the first direction D1. Here, the first low-k dielectric layer 410 may have a first thickness T1 in the first direction D1, and the first thickness T1 may be 10% to 20% of the first height H1.

A second barrier metal BP2 may be disposed on side and bottom surfaces of the first conductive line CL1. That is, the second barrier metal BP2 may be provided between the first conductive line CL1 and the first upper insulating layer 415. The second barrier metal BP2 may be formed of or include at least one of titanium (Ti), titanium nitride (TiN), or tungsten (W). The second barrier metal BP2 may prevent a metallic material, which is included in the first conductive line CL1, from being diffused into the first upper insulating layer 415.

The first conductive contact CT1 may be spaced apart from the first conductive line CL1, which does not penetrate or extend into the first conductive contact CT1, by a first distance L1 in the fourth direction D4. In the present specification, the first distance L1 may be the shortest distance, in the fourth direction D4, between the first conductive contact CT1 and the first conductive line CL1, which does not penetrate or extend into the first conductive contact CT1. The first distance L1 may be larger than or equal to 20% of the third width W3. In some embodiments, the first distance L1 may be 20% to 40% of the third width W3.

Although not shown in an enlarged view like FIG. 3, the second conductive contact CT2 and the second conductive line CL2 in the second interconnection layer INC2 may be provided to have substantially the same shapes and relative positions as those of the first conductive contact CT1 and the first conductive line CL1 described with reference to FIG. 3.

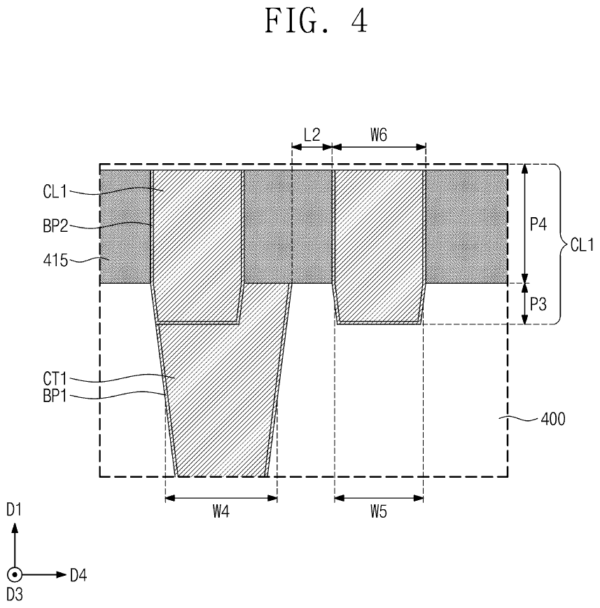

FIG. 4 is an enlarged sectional view illustrating a semiconductor device according to a comparative example and corresponding to the portion ‘CU1’ of FIG. 2. An element previously described with reference to FIG. 3 may be identified by the same reference number without repeating an overlapping description thereof.

Referring to FIG. 4, the first conductive contact CT1 may be provided to penetrate or extend into the first lower insulating layer 400. That is, the first conductive contact CT1 according to the comparative example may not penetrate or extend into the first upper insulating layer 415. Here, the first conductive contact CT1 may have a fourth width W4 in the fourth direction D4. Unlike the first conductive contact CT1 described with reference to FIG. 3, both the upper and lower portions of the first conductive contact CT1 may have a tapered shape, and thus, the fourth width W4 may decreases as a distance to the top surface 100U of the substrate 100 in the first direction D1 decreases.

The first conductive line CL1 may include a third portion P3 and a fourth portion P4 on the third portion P3. The third portion P3 may be a lower portion of the first conductive line CL1 penetrating or extending into the first lower insulating layer 400. The fourth portion P4 may be an upper portion of the first conductive line CL1 penetrating the first upper insulating layer 415.

The third portion P3 may have a fifth width W5 in the fourth direction D4. The third portion P3 may have a tapered shape, and thus, the fifth width W5 may decrease as a distance to the top surface 100U of the substrate 100 in the first direction D1 decreases. The fourth portion P4 may have a sixth width W6 in the fourth direction D4. The sixth width W6 may be larger than the fifth width W5 and may be constant in the first direction D1.

The first conductive contact CT1 may be spaced apart from the first conductive line CL1, which does not penetrate or extend into the first conductive contact CT1, by a second distance L2 in the fourth direction D4. Since an overall shape of the first conductive contact CT1 is tapered, the second distance L2 may be shorter than the first distance L1 described with reference to FIG. 3. The second distance L2 may be smaller than or equal to 10% of the sixth width W6.

In detail, the upper portion of the first conductive contact CT1 in the embodiments of FIG. 3 may have a shape with a constant width in the fourth direction D4, not a tapered shape. By contrast, the upper portion of the first conductive contact CT1 in the comparative example may be provided such that a width in the fourth direction D4 increases as a distance from the top surface 100U of the substrate 100 increases, and thus, a distance between the first conductive contact CT1 and the first conductive line CL1 adjacent thereto may be increased, compared to the embodiments of the inventive concept.

In the semiconductor device according to the comparative example, since a conductive contact of an interconnection layer has the tapered shape, the conductive contact may be spaced apart from a conductive line, which does not penetrate or extend into the conductive contact, by a small distance. As a result, an electric short problem may easily occur between the conductive contact and the conductive line, and this may lead to deterioration in electric performance of the semiconductor device. In addition, since a lower portion of the conductive line has the tapered shape, a contact area between the conductive line and the conductive contact may be small, and this may increase a contact resistance between the conductive line and the conductive contact.

By contrast, in the semiconductor device according to some embodiments of the inventive concept, the upper portion of the conductive contact of the interconnection layer may have a constant width, and thus, the conductive contact may be spaced apart from the conductive line, which does not penetrate or extend into the conductive contact, by a large distance, compared with the semiconductor device according to the comparative example. Here, the upper portion of the conductive contact may penetrate or extend into an insulating layer having a low dielectric constant. Thus, it may be possible to prevent or suppress an electric short problem between the conductive contact and the conductive lines. In addition, due to the increased distance between the conductive contact and the conductive line, it may be possible to increase the number of the conductive contacts and to increase an integration density of the semiconductor device.

Furthermore, a lower width of the conductive line according to some embodiments of the inventive concept may be larger than a lower width of the conductive line according to the comparative example. This may make it possible to increase a contact area between the conductive line and the conductive contact and to reduce an electric resistance between the conductive line and the conductive contact.

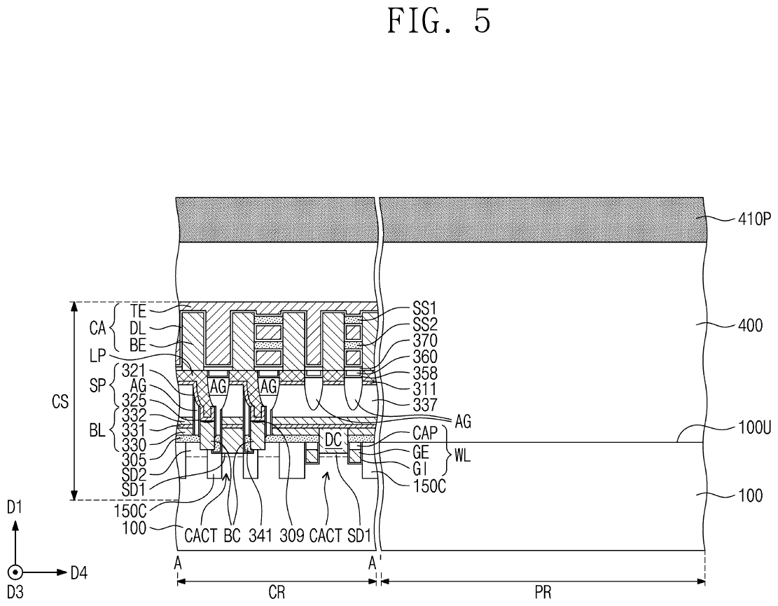

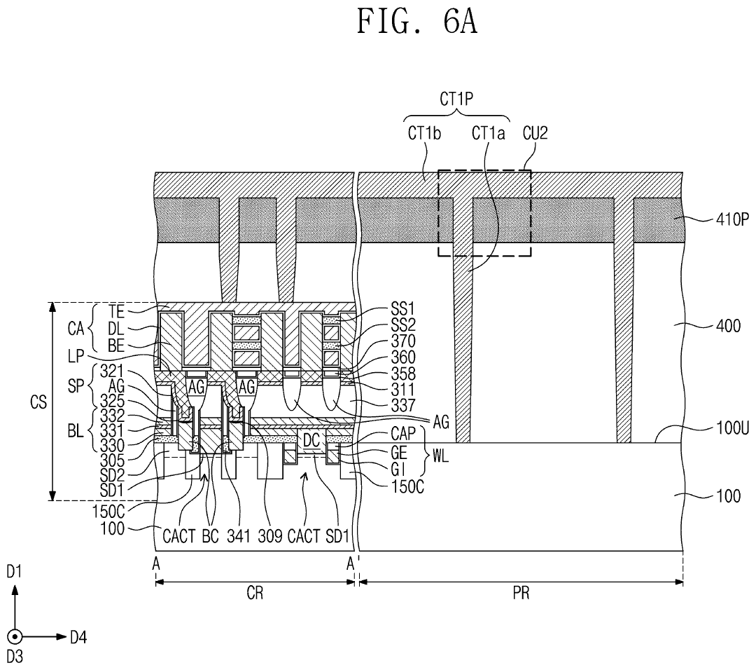

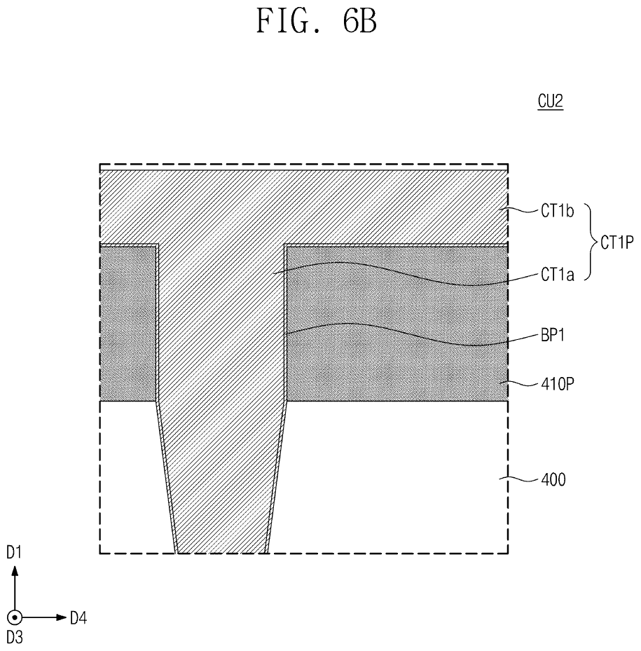

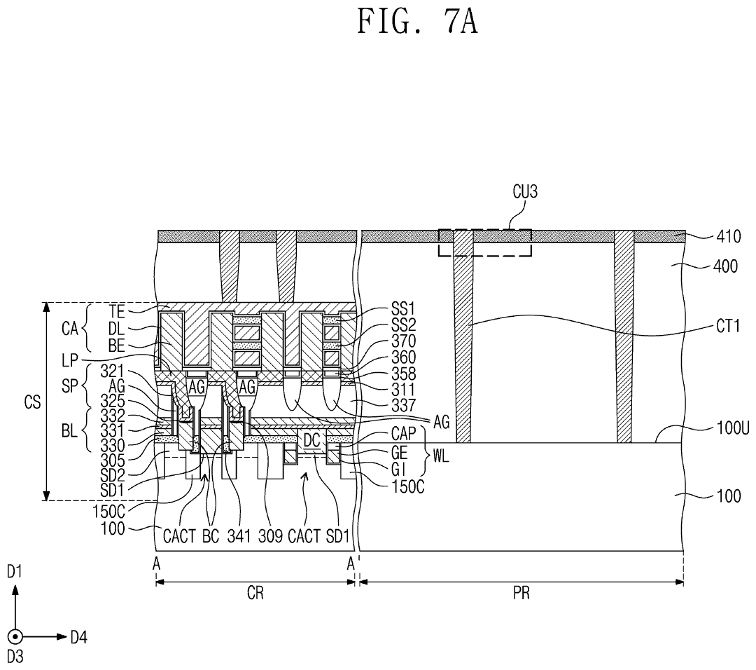

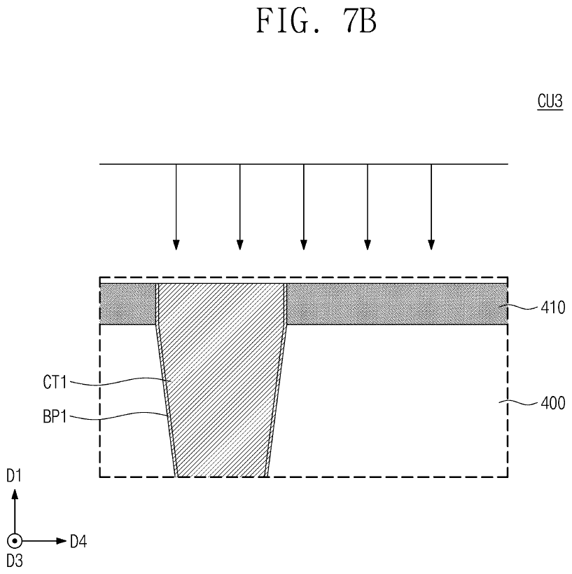

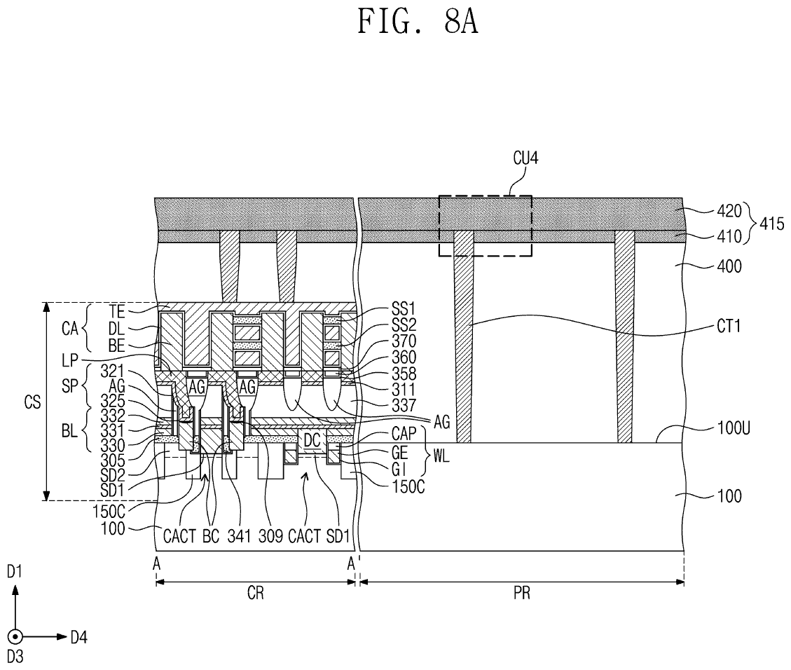

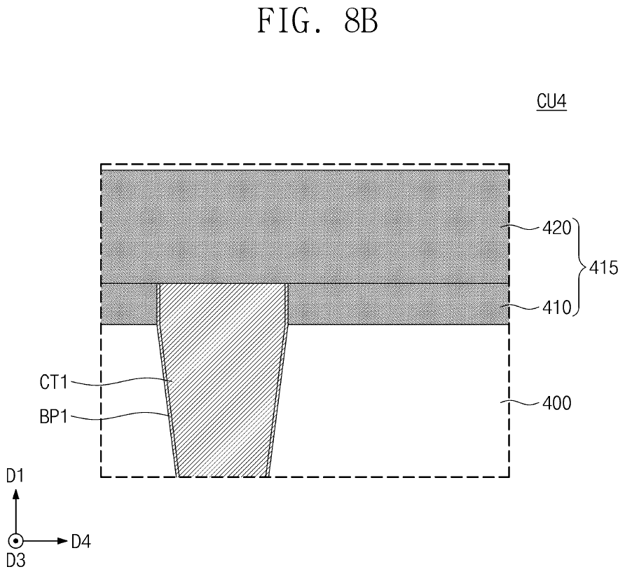

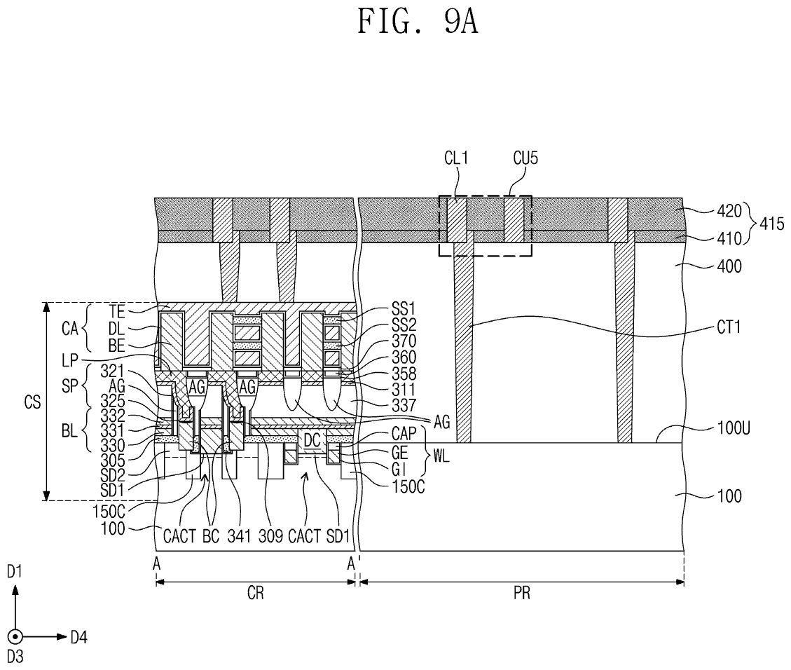

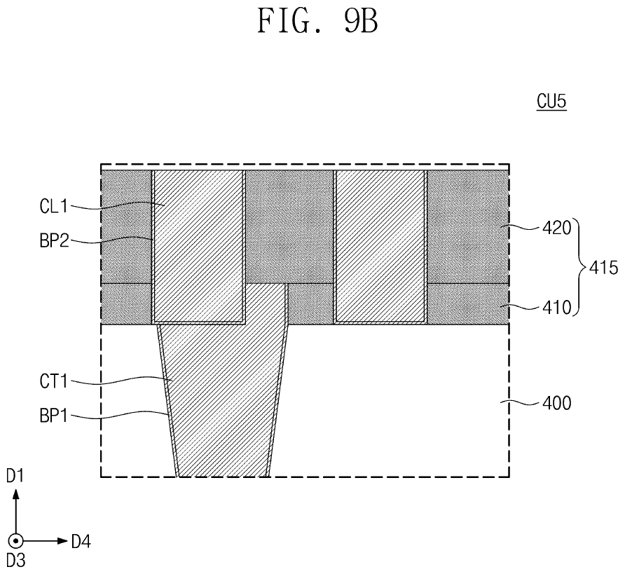

FIGS. 5, 6A, 7A, 8A, and 9A are sectional views illustrating a process of fabricating a semiconductor device, according to some embodiments of the inventive concept. FIGS. 6B, 7B, 8B, and 9B are enlarged sectional views illustrating a portion ‘CU2’ of FIG. 6A, a portion ‘CU3’ of FIG. 7A, a portion ‘CU4’ of FIG. 8A, and a portion ‘CU5’ of FIG. 9A.

Referring to FIG. 5, the substrate 100 may be prepared. The preparation of the substrate 100 may include providing the substrate 100 including the cell and peripheral regions CR and PR and forming the cell structure CS on the cell region CR of the substrate 100. The cell structure CS may include the bit line BL, the word line WL, and the capacitor CA, as described above.

Next, the first lower insulating layer 400 and a first preliminary low-k dielectric layer 410P covering, overlapping, or on the first lower insulating layer 400 may be formed on the substrate 100.

Referring to FIGS. 6A and 6B, a first preliminary conductive contact CT1P may be formed to penetrate or extend into the first lower insulating layer 400 and the first preliminary low-k dielectric layer 410P. The first preliminary conductive contact CT1P may include a vertical portion CT1a, which is provided to penetrate or extend into the first lower insulating layer 400 and the first preliminary low-k dielectric layer 410P in the first direction D1, and a horizontal portion CT1b, which is provided on the first preliminary low-k dielectric layer 410P and extends in the fourth direction D4.

In detail, the formation of the first preliminary conductive contact CT1P may include etching the first lower insulating layer 400 and the first preliminary low-k dielectric layer 410P to form a plurality of contact holes. The contact holes on the cell region may be formed to expose a top surface of the top electrode TE of the capacitor CA, and the contact holes on the peripheral region may be formed to expose the top surface 100U of the substrate 100. The formation of the first preliminary conductive contact CT1P may further include forming the first barrier metal BP1 to cover, overlap, or be on side and bottom surfaces of each of the contact holes and a top surface of the first preliminary low-k dielectric layer 410P and depositing a metallic material on the first barrier metal BP1 to partially or completely fill an unfilled space of the contact holes and cover, overlap, or be on the first preliminary low-k dielectric layer 410P.

Here, since, as previously described with reference to FIG. 2, the first preliminary low-k dielectric layer 410P has an etch rate higher than the first lower insulating layer 400, a shape of the vertical portion CT1a in the first lower insulating layer 400 may be different from that in the first preliminary low-k dielectric layer 410P. In detail, a width, in the fourth direction D4, of the vertical portion CT1a penetrating the first lower insulating layer 400 may decrease as a distance from the top surface 100U of the substrate 100 in the first direction D1 decreases. A width, in the fourth direction D4, of the vertical portion CT1a penetrating the first preliminary low-k dielectric layer 410P may be substantially constant, regardless of a position in the first direction D1.

Referring to FIGS. 7A and 7B, a grinding process, which includes a chemical-mechanical polishing (CMP) process or a dry etching process, may be performed on the first preliminary conductive contact CT1P and the first preliminary low-k dielectric layer 410P. As a result of the grinding process on the first preliminary conductive contact CT1P, the horizontal portion CT1b may be removed, and only a portion of the vertical portion CT1a may be left. In some embodiments, the grinding process may be performed to reduce a thickness of the first preliminary low-k dielectric layer 410P in the first direction D1. The left portion of the vertical portion CT1a may form the first conductive contact CT1. The first preliminary low-k dielectric layer 410P, which is thinned by the grinding process, may form the first low-k dielectric layer 410.

Referring to FIGS. 8A and 8B, the second low-k dielectric layer 420 may be formed on the first low-k dielectric layer 410 and the first conductive contact CT1. The second low-k dielectric layer 420 may cover, overlap, or be on the top surface of the first conductive contact CT1. The second low-k dielectric layer 420 may constitute or be included in the first upper insulating layer 415, which is formed on the first lower insulating layer 400.

Referring to FIGS. 9A and 9B, the first conductive lines CL1 may be formed to penetrate or extend into the first upper insulating layer 415.

In detail, the formation of the first conductive line CL1 may include etching the second low-k dielectric layer 420, the first low-k dielectric layer 410, and a portion of an upper portion of the first conductive contact CT1 to form a plurality of line holes, forming the second barrier metal BP2 to cover, overlap, or be on side and bottom surfaces of each of the line holes, and filling the line holes, which are covered with over overlapped by the second barrier metals BP2, with a metallic material.

The first conductive line CL1, which does not penetrate or extend into the first conductive contact CT1, may be formed by the same process as the first conductive line CL1, which is formed to penetrate or extend into the first conductive contact CT1, except for the step of etching the portion of the upper portion of the first conductive contact CT1.

Here, since as described with reference to FIG. 2, the first upper insulating layer 415 includes a material with a high etch rate, a width of the first conductive line CL1 in the fourth direction D4 may be substantially constant, regardless of a position in the first direction D1.

Next, although not shown, a process, which is similar to the process described with reference to FIGS. 5, 6A, 7A, 8A, and 9A may be performed to form the second and third interconnection layers INC2 and INC3 on the first upper insulating layer 415, and thus, the semiconductor device may be fabricated to have the structure of FIG. 2.

According to some embodiments of the inventive concept, in an interconnection layer of a semiconductor device, an upper portion of a conductive contact may penetrate or extend into an insulating layer, which includes a low-k dielectric material with a high etch rate. The upper portion of the conductive contact may have a shape with a substantially constant width, not a tapered shape. In this case, a distance between the conductive contact and the conductive line may be increased, and thus, it may be possible to suppress an electric short problem between the conductive contact and the conductive line. In addition, it may be possible to increase the number of the conductive contacts, which can be placed between the increased distance, and to increase an integration density of the semiconductor device.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate; and
an interconnection layer on the substrate,
wherein the interconnection layer comprises an insulating layer, a conductive line, and a conductive contact,
wherein the insulating layer comprises an upper insulating layer on a lower insulating layer,
wherein the conductive contact extends into a lower portion of the upper insulating layer and extends into the lower insulating layer,
wherein the conductive line is on the lower insulating layer and intersects the upper insulating layer, and
wherein the upper insulating layer comprises a low-k dielectric material.

2. The semiconductor device of claim 1, wherein a dielectric constant of the low-k dielectric material in the upper insulating layer is equal to or less than 3.5.

3. The semiconductor device of claim 1, wherein the low-k dielectric material in the upper insulating layer comprises at least one of SiCOH, SiOF, or polyimide, and
wherein the lower insulating layer comprises silicon oxide.

4. The semiconductor device of claim 1, wherein a width of a lower portion of the conductive line in a first direction parallel to a top surface of the substrate is substantially constant in a second direction perpendicular to the top surface of the substrate.

5. The semiconductor device of claim 4, wherein a top surface of the lower insulating layer is lower than a top surface of the conductive contact with respect to the substrate.

6. The semiconductor device of claim 4, wherein a distance between the conductive contact and the conductive line is in a range of 20% to 40% of a width of the conductive line.

7. The semiconductor device of claim 6, further comprising:
a cell structure between the substrate and the interconnection layer,
wherein the cell structure comprises a capacitor,
wherein the capacitor comprises:
a plurality of bottom electrodes which are spaced apart from each other in the first direction;
a top electrode on the bottom electrodes; and
a dielectric layer that extends between each of the bottom electrodes and the top electrode, and
wherein the conductive contact is on the top electrode.

8. A semiconductor device, comprising:
a substrate;
a cell structure on the substrate; and
an interconnection layer on the cell structure,
wherein the interconnection layer comprises an insulating layer, a conductive line, and a conductive contact,
wherein the insulating layer comprises an upper insulating layer on a lower insulating layer,
wherein the conductive contact comprises a first portion and a second portion on the first portion,
wherein the first portion extends into the lower insulating layer,
wherein the second portion extends into a lower portion of the upper insulating layer,
wherein the first portion has a first width in a first direction parallel to a top surface of the substrate,
wherein the second portion has a second width in the first direction,
wherein the first width decreases as a distance to the top surface of the substrate, in a second direction perpendicular to the top surface of the substrate, decreases, and
wherein the second width is substantially constant in the second direction.

9. The semiconductor device of claim 8, wherein the upper insulating layer comprises at least one of SiCOH, SiOF, or polyimide.

10. The semiconductor device of claim 8, wherein the conductive line extends into the upper insulating layer and extends into the second portion of the conductive contact.

11. The semiconductor device of claim 8, further comprising:
a first barrier metal between the conductive contact and the lower insulating layer and between the conductive contact and the upper insulating layer; and
a second barrier metal between the conductive line and the upper insulating layer.

12. The semiconductor device of claim 8, wherein the upper insulating layer is on a side surface of the conductive line.

13. The semiconductor device of claim 8, wherein a thickness of the lower insulating layer is in a range of 10% to 20% of a height of the conductive line.

14. The semiconductor device of claim 8, wherein a width of a lower portion of the conductive line in the first direction is substantially constant in the second direction.

15. The semiconductor device of claim 8, wherein the second portion of the conductive contact is on the lower insulating layer.

16. A semiconductor device, comprising:
a semiconductor substrate comprising a cell region and a peripheral region adjacent the cell region and including cell active patterns on the cell region;
word lines on the semiconductor substrate that intersect the cell active patterns;
bit lines on the semiconductor substrate that intersect the word lines;
a storage node contact on an end portion of each of the cell active patterns;
a landing pad on the storage node contact;
a capacitor on the landing pad; and
an interconnection layer on the capacitor,
wherein the interconnection layer comprises an insulating layer, a plurality of conductive contacts, and a plurality of conductive lines which are spaced apart in a first direction parallel to a top surface of the semiconductor substrate,
wherein the insulating layer comprises an upper insulating layer on a lower insulating layer,
wherein each of the conductive contacts extends into a lower portion of the upper insulating layer and extends into the lower insulating layer,
wherein a first conductive line of the plurality of conductive lines extends into an upper portion of a first conductive contact of the plurality of conductive contacts,
wherein the upper insulating layer comprises a first dielectric material,
wherein the lower insulating layer comprises a second dielectric material, and
wherein a first dielectric constant of the first dielectric material is less than a second dielectric constant of the second dielectric material.

17. The semiconductor device of claim 16, wherein a shortest distance, in the first direction, between the first conductive contact and the first conductive line, which does not extend into the first conductive contact, is greater than or equal to 20% of a width of the first conductive line in the first direction.

18. The semiconductor device of claim 16, wherein a top surface of the lower insulating layer is lower than a top surface of the first conductive contact with respect to the semiconductor substrate.

19. The semiconductor device of claim 16, wherein a width of the first conductive contact in the first direction is substantially constant from a bottom surface of the first conductive line to a top surface of the first conductive contact.

20. The semiconductor device of claim 16, wherein the first dielectric material comprises at least one of SiCOH, SiOF, or polyimide, and
wherein the second dielectric material comprises silicon oxide.
